(19) United States
(12) Patent Application Publication
(10) Pub. No.: US 2008/0246044 A1
(43) Pub. Date: Oct. 9, 2008

(54) LED device with combined Reflector and Spherical Lens

(76) Inventor: Siew It Pang, Bayan Lepas (MY)

Correspondence Address: Kathy Manke;Avago Technologies Limited, 4380 Ziegler Road, Fort Collins, CO, 80525, US

(21) Appl. No.: 11/733,105

(22) Filed: Apr. 9, 2007

(51) Int. Cl. H01L 33/00; H01L 29/22; H01L 29/227

(52) U.S. Cl. 257/98

(57) ABSTRACT

A light source and method for making the same are disclosed. The light source includes a substrate having a top surface, a die, and a first encapsulating layer. The die includes an LED attached to the top surface and electrically connected to traces in the substrate that power the LED. The first dome covers the die and is in contact with the top surface, the dome having an angle of contact greater than 90° with respect to the top surface. The first dome has an outer surface that includes a truncated sphere characterized by a center for the spherical portion of the surface, and the die is situated at a position below the center. A second dome can be provided around the outside of the first dome. In addition, the first dome may include light converting and/or scattering materials.

### BACKGROUND OF THE INVENTION

Light-emitting diodes (LEDs) are attractive candidates for the replacement of conventional light sources based on incandescent and fluorescent lights. LEDs have significantly higher power efficiencies than incandescent lights and have much greater lifetimes. In addition, LEDs do not require the high voltage systems associated with fluorescent lights and can provide light sources that more nearly approximate “point sources” than fluorescent fixtures. The latter feature is particularly important for light sources that utilize collimating or other imaging optics.

LEDs based on the GaN family of materials achieve very high electricity to light conversion efficiencies within the active layer of the LED. However, these materials have very high indexes of refraction, which inhibit the extraction of the light from the LED die. A significant fraction of the light generated in the active region of the LED is trapped by internal reflection between the top surface of the die and the bottom surface of the die or the interface between the LED and the underlying substrate. Hence, the high conversion efficiency is not fully realized in practice.

Two strategies are utilized to mitigate the effects of the internal reflection. Part of the light that is trapped between the top and bottom layers of the LED by internal reflection strikes the edge of the die and exits through the edge. This light is traveling at angles that are generally orthogonal to the direction of light that leaves the top surface of the die. Hence, to recover this portion of the light, some form of reflector is generally utilized. For example, the LED is often mounted in a reflective cup having reflective sides that slant outwards. The light striking these sides is redirected to the same direction as light leaving the top surface of the LED die, and hence, this light is effectively recovered.

Unfortunately, most of the light that is internally reflected is lost due to absorption before that light reaches the sides of the die. In addition, the resultant light source has an effective diameter that is greater than that of the die, since the source appears to be a point source originating at the die location surrounded by an annular source that is the result of the light that is reflected off of the reflector. The increased size of the source makes it more difficult to process the light using conventional optical elements that are located near the die. In addition, the cost of utilizing a reflector both in terms of parts and labor is a significant factor in the cost of the packaged LED.

Hence, schemes that reduce the amount of light that is trapped by internal reflection have been pursued. One such scheme utilizes a layer of material having an index of refraction that is significantly higher than air. This layer reduces the mismatch between the index of refraction of air and that of the LED materials, and hence, allows a significant fraction of the light that would have been trapped in the die to exit into the layer of material. To prevent the loss of this light due to internal reflection at the boundary between this layer and the air outside the LED, the surface of this layer must be convex and separated from the die by a significant distance that depends on the effective diameter of the light source. Hence, an encapsulating layer must be created with such a surface, and the surface must be a significant distance from the die and reflector to assure that all of the light that leaves the die can escape from the encapsulating material.

The surface of this convex dome also determines the angular distribution of light leaving the LED, since this surface acts as a lens. To provide a wide viewing angle, the outer surface must be molded into a particular shape, e.g., a spherical surface. The cost of providing this molded interface is significant.

### SUMMARY OF THE INVENTION

The present invention includes a light source and method for making the same. The light source includes a substrate having a top surface, a die, and a first encapsulating layer. The die includes an LED attached to the top surface and electrically connected to traces in the substrate that power the LED. The first dome covers the die and is in contact with the top surface, the dome having an angle of contact greater than 90° with respect to the top surface. In one aspect of the invention, the first dome has an outer surface that includes a truncated sphere that is characterized by a center for the spherical portion of the surface, and the die is situated at a position below the center. The dome can cover a portion of the sidewalls of the die. A second dome can be provided around the outside of the first dome. In addition, the first dome may include light converting and/or scattering materials.

### BRIEF DESCRIPTION OF THE DRAWINGS

FIG. 1 is a cross-sectional view of a prior art packaged LED device.

FIG. 2 is a cross-sectional view of another prior art packaged LED arrangement.

FIG. 3 is a cross-sectional view of a light source 40 according to one embodiment of the present invention.

FIG. 4 is a cross-sectional view of a light source 50 according to another embodiment of the present invention.

FIG. 5 is a cross-sectional view of another embodiment of a light source according to the present invention.

FIG. 6 is a cross-sectional view of another embodiment of a light source according to the present invention.

FIG. 7 is a cross-sectional view of another embodiment of a light source according to the present invention.

FIG. 8 is a cross-sectional view of another embodiment of a light source according to the present invention.

FIGS. 9A-9C illustrate the use of a contact angle to measure the degree to which a substance wets a surface.

FIG. 10 is a cross-sectional view of light source 80 shown in FIG. 8 with the angle of contact shown thereon.

FIGS. 11A-11D illustrate one embodiment of a method for the fabrication of a light source according to the present invention.

### DETAILED DESCRIPTION OF THE PREFERRED EMBODIMENTS OF THE INVENTION

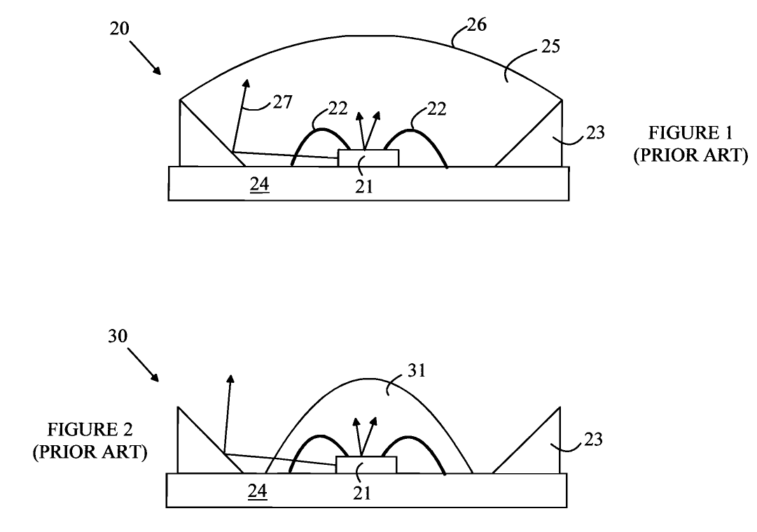

The manner in which the present invention provides its advantages can be more easily understood with reference to FIG. 1, which is a cross-sectional view of a prior art packaged LED device. Device 20 includes a die 21 that is mounted on a substrate 24. Die 21 can be connected to traces in substrate 24 by contacts on the bottom of the die or by wire bonds such as the wire bonds shown at 22. A reflective cup 23 is either mounted on substrate 24 by a separate operation or created as part of substrate 24. After the die is mounted and connected electrically, a layer 25 of clear encapsulating material is used to fill the cup. The top surface 26 of the encapsulating layer is convex with a radius of curvature such that light leaving the die and passing through the encapsulating layer will strike surface 26 at an angle that is less than the critical angle, and hence, the light will exit the encapsulating layer. To assure that all of the light striking surface 26 has the correct range of angles, die 21 must appear as a more or less point source when viewed from surface 26. In addition, the light 27 that leaves the side surface of die 21 and strikes reflector 23 must also strike surface 26 at angles less than the critical angle to assure that the side-emitted light is not trapped in layer 25.

Surface 26 can be created by molding the layer of material over die 21. The molding operation adds to the cost. In addition, a significant quantity of clear encapsulant material is needed to fill the cup and provide the convex surface.

The large amount of molding material and the molding process can be reduced by using an encapsulating method in which a droplet of encapsulant is placed over the die and hardens to form the dome-shaped surface. Refer now to FIG. 2, which is a cross-sectional view of another prior art packaged LED arrangement. LED 30 includes a droplet of encapsulant shown at 31. The encapsulant is applied in a semi-liquid state and then cured. The shape of the convex surface is determined by the surface tension of the liquid and the properties of the surface on which the droplet is applied. Hence, the shape of the air-encapsulant surface is not easily controlled. In addition, the size of the light source is still much greater than the size of the die.

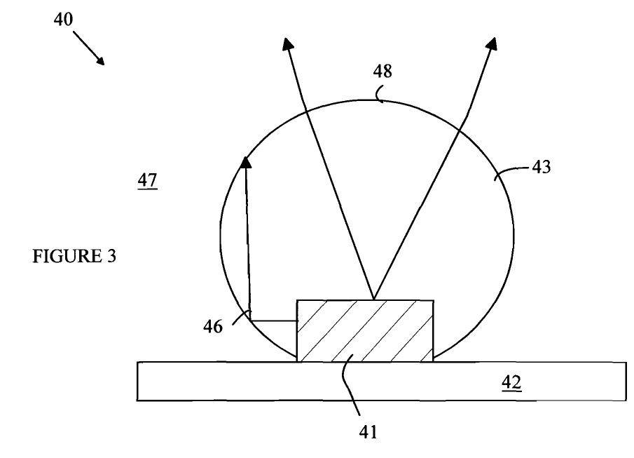

The present invention overcomes these problems by utilizing a droplet design in which the droplet acts both as the light extraction layer and a lens without requiring a separate molding operation. Refer now to FIG. 3, which is a cross-sectional view of a light source 40 according to one embodiment of the present invention. Light source 40 includes a die 41 having an LED thereon and an encapsulant dome 43 that encapsulates the top surface of die 41 and a portion of the side walls of the die. The encapsulant dome provides the functions of the convex dome and the reflector described above. Encapsulant dome 43 is preferably spherical in shape; however, some departure from this preferred shape can be accommodated without significantly reducing the benefits of the encapsulant layer.

Encapsulant dome 43 reduces the amount of light that is trapped within die 41 due to the high index of refraction of the materials from which die 41 is constructed. The outer surface of encapsulating dome 43 acts as a spherical lens in addition to facilitating the escape of the light from encapsulating dome 43 into the medium 47, which is typically air. The spherical lens also increases the range of angles from which the light leaving light source 40 can be viewed.

In the embodiment shown in FIG. 3, encapsulating dome 43 extends below the active region on the die. The material from which encapsulating dome 43 is constructed has an index of refraction that is significantly higher than that of the surrounding medium 47. Hence, the boundary between encapsulating dome 43 and medium 47 will internally reflect light if the light strikes that boundary at an angle greater than the critical angle. In region 48, the light strikes the surface of encapsulating dome 43 at angles less than the critical angle, and hence the light escapes encapsulating dome 43. However, in region 46, light leaving the sides of die 41 will strike surface 46 at angles greater than the critical angle, and hence, be reflected toward the upper surface 48 of encapsulating dome 43. As will be explained in more detail below, this feature of the present invention is useful in embodiments in which encapsulating dome 43 includes a phosphor that converts light from die 41 to light having a different spectrum.

The shape of encapsulating dome 43 is determined by the interaction between the material from which encapsulating dome 43 is constructed and the surface on which encapsulating dome 43 is deposited. In practice, encapsulating dome 43 is constructed by depositing a droplet of a precursor material onto die 41. The material will bead to form a spherical droplet if the surface on which it is deposited is not wet by the material of the precursor. Once the droplet has been deposited and given time to reach equilibrium, the precursor material is cured to provide a solid spherical dome. In the embodiment shown in FIG. 3, encapsulating dome 43 is constructed from a material that wets die 41 but not the surface of substrate 42. Hence, when the droplet of precursor material is deposited on the upper surface of die 41, the material covers the surface and runs down the sides until it encounters the upper surface of substrate 42. Since the precursor does not wet this surface, the precursor does not spread over the surface of substrate 42. Instead, the droplet forms a spherical bead.

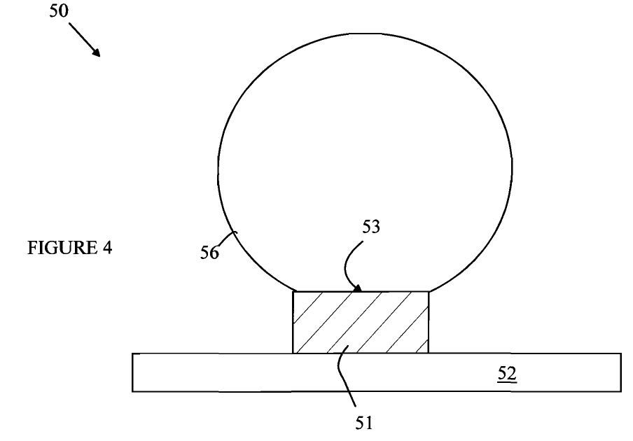

By properly choosing the material from which the die surfaces are covered, other spherical dome arrangements can be generated. Refer now to FIG. 4, which is a cross-sectional view of a light source 50 according to another embodiment of the present invention. Light source 50 includes an LED containing die 51 that is mounted on a substrate 52. The top surface of die 51 is coated with a material that is wet by the precursor material from which dome 56 is constructed; however, the side surfaces of die 51 are not wet by the precursor material. As a result, when a droplet of the precursor material is applied to the top surface 53 of die 51, the material forms a spherical droplet on the top surface 53 of the die but does not run down the sides of the die.

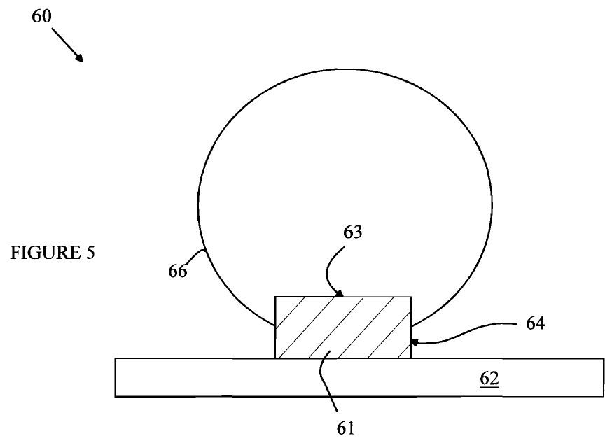

Dome arrangements that are intermediate between those shown in FIGS. 3 and 4 can also be achieved by making use of the viscosity of the precursor material and the different degrees with which the various surfaces are wet by the precursor material. One such arrangement is shown in FIG. 5, which is a cross-sectional view of another embodiment of a light source according to the present invention. Light source 60 is constructed from a die 61 that includes an LED. Die 61 is mounted on substrate 62 and includes a top surface 63 and side surfaces 64. Top surface 63 is coated with a different material than the material exposed on the side surfaces 64. The precursor from which dome 66 is constructed wets surface 63 to a greater degree than the precursor wets sides 64. It is also assumed that the precursor material has a relatively high viscosity. Hence, when the precursor material is dispensed on top surface 63, the precursor material covers top surface 63 and forms a substantially spherical droplet. The precursor material then begins to slowly move down the sides. If the precursor material is cured before it reaches substrate 62, a dome 66 that extends partially down the sides of die 64 can be obtained.

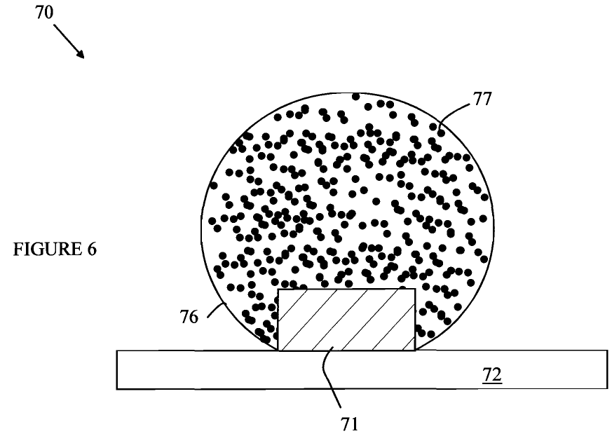

The embodiments of the present invention discussed above utilize a clear dome material. However, embodiments in which phosphors are dispersed within the dome material can also be constructed. Refer now to FIG. 6, which is a cross-sectional view of another embodiment of a light source according to the present invention. Light source 70 is constructed from a die 71 that is mounted on a substrate 72 having a surface that is not wet by the precursor material used to construct dome 76. The precursor material has phosphor particles 77 suspended in the precursor such that the dome has phosphor particles suspended therein when the precursor is cured. The phosphor particles include a light conversion material that converts light emitted by the LED on die 71 to light of a different spectrum. For example, die 71 could emit blue light that is converted by the light conversion material to yellow light. The combination of the yellow light and the remaining unconverted blue light provides a light source that is perceived as being white by a human observer.

As noted above, light leaving the sides of die 71 will be internally reflected by dome 76 and trapped within dome 76. The trapped light will eventually be converted by the phosphor particles or absorbed. Hence, the surface of dome 76 provides a reflector function that is analogous to the reflectors incorporated in conventional white LED light sources. However, unlike conventional reflectors, the surface of dome 76 can be much smaller in size and requires no additional fabrication steps. In addition, dome 76 appears to be a uniformly emitting sphere when LED 71 is activated.

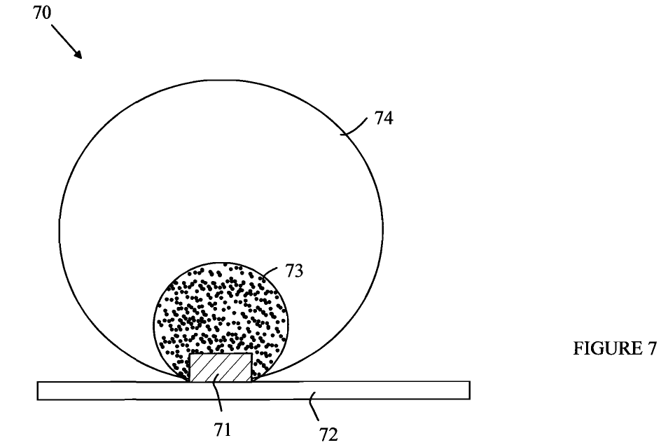

Since the light generated by the phosphor particles is emitted at all angles, some portion of that light will be internally reflected within dome 76. The amount of light that is trapped can be reduced by providing a second concentric sphere around dome 76. Refer now to FIG. 7, which is a cross-sectional view of another embodiment of a light source according to the present invention. Light source 70 includes a die 71 that includes an LED that emits light of a first wavelength. The die is enclosed in a first spherical dome 73 constructed from a clear material that includes phosphor particles. The clear material is chosen such that the surface of substrate 72 is not wet by the precursor material used in constructing dome 73. After dome 73 is solidified, a second clear dome 74 is constructed in a similar manner, preferably from the same clear material used to suspend the phosphor particles in dome 73. This material will wet the surface of dome 73 but not that of substrate 72. Hence, dome 74 will also be a substantially spherical dome. Dome 74 has a diameter that is sufficient to facilitate the transfer of light from dome 73 to the medium outside dome 74, which is typically air.

The above-described embodiments of the present invention shown in FIG. 3 depend on having a precursor material that preferentially wets the top surface of the die relative to the side surfaces. If the precursor material can be cured with sufficient speed, some affinity of the precursor for the material on the side surfaces can be tolerated, since the precursor will move relatively slowly down the sides of the die. During this process, the dome remains substantially spherical.

It should be noted that the top surface of LED dies are typically covered with a material that protects the surface. Glass or polyamides are often used for this purpose. The layer is applied to the top surface of the wafer after the various semiconductor layers have been deposited but before the final connection pads are deposited on the top surface. After the wafer has been finished, the wafer is cut into the individual dies. Hence, the top surface will be covered by a material that is different from the material exposed on the side surfaces of the die.

Similarly, the LEDs are typically constructed from layers of material in a first material system that are deposited on the top surface of a wafer constructed from a second material. For example, GaN LEDs used to provide blue-emitting LEDs are constructed on sapphire wafers. When the wafers are diced to produce the individual dies, both the wafer material and the deposited semiconductor layers are exposed. These materials will, in general, have different wetting properties with respect to a particular dome precursor. Hence, if a dome precursor that has a greater affinity for the semiconductor layers than the underlying wafer can be used, a dome that stops at the wafer can also be constructed.

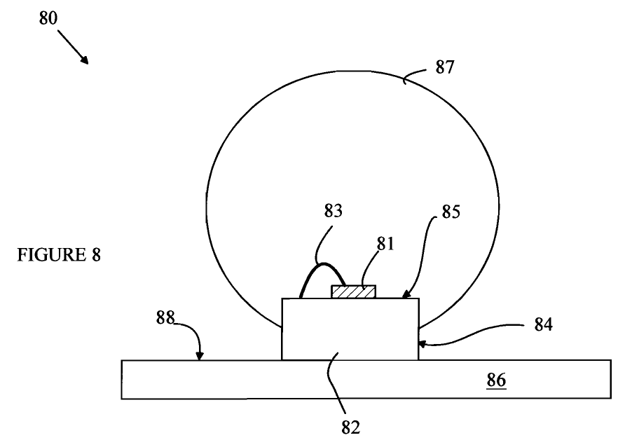

The above-described embodiments utilize an encapsulating dome in which just the die or a portion thereof is within the encapsulating dome. However, embodiments in which the encapsulating dome extends around the die and a portion of an underlying substrate can also be constructed. Refer now to FIG. 8, which is a cross-sectional view of another embodiment of a light source according to the present invention. Light source 80 is constructed from a die 81 that is mounted on first substrate 82. Substrate 82 is part of a larger substrate 86. Die 81 includes an LED that is connected electrically to traces in substrate 82. The contacts on die 81 can be connected to the traces in question by wire bonds such as wire bond 83 or contacts on the underside of die 81 that mate with corresponding contacts on substrate 82. Encapsulating dome 87 is constructed from a material that wets surface 85 more than surface 84 on the sides of substrate 82. Hence, the encapsulant precursor forms a spherical surface over die 81. The extent to which encapsulating dome 87 extends down the sides of substrate 84 is controlled by the viscosity of the precursor material from which encapsulating dome 87 is constructed and by the time that is allowed to elapse between the deposition of a droplet of precursor material on surface 85 and the time the precursor cures to form the final encapsulating dome.

If surface 88 of substrate 86 is not wet by the precursor material, then the movement of the encapsulating dome down surface 84 will stop when the precursor material reaches surface 88. In this case, the entire portion of substrate 82 that extends above surface 88 will be encapsulated by the dome. By providing such a non-wetting surface, the dome will have a reproducible shape and size that is determined by the volume of precursor material that is dispensed. Hence, a precisely shaped dome can be provided by a simple and inexpensive fabrication process.

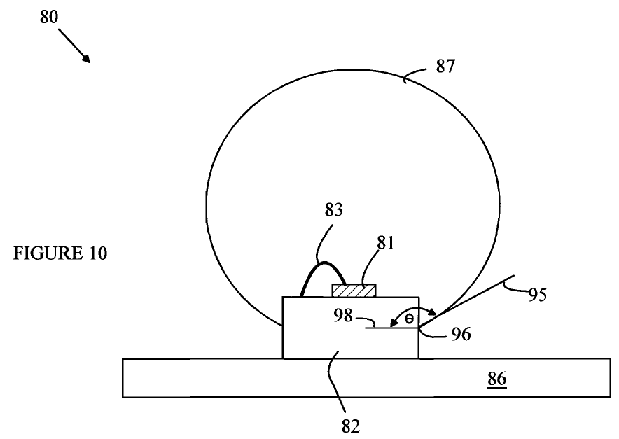

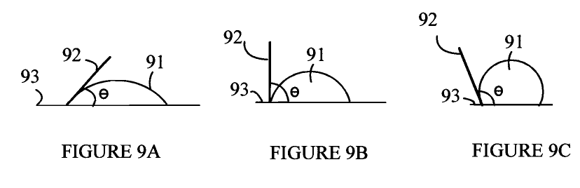

The above-described embodiments refer to the degree to which the precursor material wets the various surfaces. In general, the degree to which a substance wets a surface depends on a number of properties; however, the contact angle between the surface of a droplet of the material and the surface can be used as a measurement of the degree to which the substance wets the surface in question. Refer now to FIGS. 9A-9C, which illustrate the use of the contact angle to measure the degree to which a substance wets a surface. In general, the contact angle is defined to be the angle at which the tangent to the surface of a droplet of the liquid intersects the surface at the edge of the droplet. This angle is denoted by θ in FIGS. 9A-9C. Refer now to FIG. 9A, which is a cross-sectional view of a droplet 91 of material that has been deposited on a surface 93. The tangent to the surface of droplet 91 is shown at 92. A material is said to wet the surface if the contact angle is less than 90°. This is the situation shown in FIG. 9A and is the configuration that is typically utilized in prior art droplet encapsulation methods. A contact angle of 90° or greater generally characterizes a surface as not-wettable. The case in which the contact angle is 90° is shown in FIG. 9B. Finally, FIG. 9C illustrates the case in which the contact angle is greater than 90°.

In the above-described embodiments, the outer surface of the encapsulating dome is substantially a spherical surface that contacts either a surface that is parallel to the top surface of the die as shown in FIGS. 3 and 6 or a surface that is substantially at right angles to the top surface of the die as shown in FIGS. 4 and 8. To simplify the following discussion, the term “angle of contact” will be defined as the angle at which a surface that is parallel to the top surface of the die intersects the tangent to the outer surface of the encapsulating dome at the point at which that surface contacts the substrate independent of whether the contact point is on the surface that is parallel to the top surface of the die. This definition can be more clearly understood with reference to FIG. 10, which is a cross-sectional view of light source 80 shown in FIG. 8 with the angle of contact shown thereon. The tangent to the surface of the encapsulating dome at point of contact 96 is shown at 95. A line that is parallel to the top surface of die 81 is shown at 98. The angle of contact is labeled as θ.

The preferred angle for the angle of contact will depend on the specific application; however, to provide a substantially spherical encapsulating dome, an angle of contact that is greater than 90° is preferred. In some embodiments, the angle of contact is greater than 150°.

The encapsulating dome can be constructed from any clear material that has a precursor with the desired wetting characteristics. For dies constructed in the GaN material system, it has been found that silicone and clear epoxy can be utilized. UV curable epoxy has the further advantage of allowing the encapsulating dome to be “frozen” at the desired point in relationship to the sides of the die or substrate. If the material of a substrate is wet by the precursor, the substrate surface can be coated with Teflon, fluoropolymer or boron nitride.

The preferred shape of the encapsulating dome is that of a truncated sphere in which the encapsulating dome extends at least part of the way down the sides of the die. This shape assures that the light leaving the sides of the die is reflected upwards, since the angle at which that side-emitted light strikes the encapsulating dome surface is greater than the critical angle for the encapsulating dome surface.

The above-described embodiments utilize an inner encapsulating dome that includes a phosphor; however, other components that affect the optical characteristics of the encapsulating dome could also be included in the encapsulating dome. For example, other light converting materials such as luminescent materials or dyes could be added to the precursor material. In addition, diffusants such as SiO₂ particles could also be added to randomize the light generated by the LED that is not converted by the phosphor to light having a new spectrum.

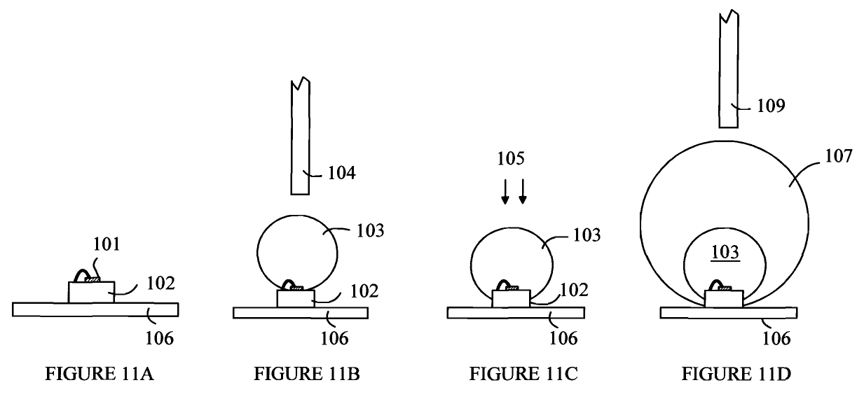

As noted above, the present invention provides a significant reduction in the fabrication cost of an LED light source. Refer now to FIGS. 11A-11D, which illustrate one embodiment of a method for the fabrication of a light source according to the present invention. Initially, the die 101 containing the LED is attached to substrate 102 utilizing an appropriate adhesive. Substrate 102 includes traces that provide power to die 101. In the example shown in FIG. 11A, one of the traces is on the bottom side of die 101 and connects to a trace under the die, and the other trace is on the top surface of die 101 and is connected by a wire bond to a trace through a bond pad in the top surface of substrate 101. After the die is connected, a droplet 103 of a first precursor is dispensed onto the top surface of substrate 102 such that it covers the die and the top surface from a dispenser 104 as shown in FIG. 11B. After the liquid precursor has had time to move part of the way down the sides of substrate 102, the precursor material is cured using light or heat as shown at 105 in FIG. 11C. As noted above, droplet 103 can include phosphor particles or other light converting or scattering materials. In this case, it is advantageous to provide another encapsulating dome around the outside of droplet 103 to improve the transfer of light from droplet 103 to the air outside the light source. In this case, a second droplet of clear precursor material 107 is dispensed by a dispenser 109 over the outer surface of droplet 103. It is assumed that the precursor material does not wet the surface of the second substrate 106. Hence, droplet 107 forms a concentric truncated spherical dome around droplet 103 and the angle of contact between droplet 107 and substrate 102 or 106 remains greater than 90°. After droplet 107 has settled to its desired position, the precursor material is cured to provide a solid second encapsulating dome.

Various modifications to the present invention will become apparent to those skilled in the art from the foregoing description and accompanying drawings. Accordingly, the present invention is to be limited solely by the scope of the following claims.

1. A light source comprising:
a substrate having a first top surface;
a die comprising a second top surface and an LED, said die being attached to said first top surface; and
a first dome covering said second top surface of said die, said first dome making direct contact with said second top surface and having an angle of contact greater than 90% with respect to said second top surface.

2-3. (canceled)

4. The light source of claim 1 wherein said die further comprises a bottom surface and a plurality of side walls connecting said first top surface to said bottom surface and wherein said first dome covers at least a portion of said side walls of said die.

5. The light source of claim 1 wherein said first dome comprises a transparent epoxy or silicone.

6. The light source of claim 1 wherein said first top surface of said substrate on which said die is mounted is surrounded by a recessed area having side surfaces extending from said first top surface and wherein said first dome covers a portion of said side surfaces.

7. The light source of claim 1 further comprising a second dome surrounding said first dome, and wherein said first dome comprises a light converting material that converts light emitted by said LED to light having a different spectrum.

8. The light source of claim 7 wherein said light converting material comprises particles of a phosphor.

9-10. (canceled)

11. A method for fabricating a light source, said method comprising:
attaching a die having an LED thereon to a substrate, said die having a top surface, a bottom surface, and a plurality of side surfaces, said die being attached to said substrate by said bottom surface;
connecting contacts on said LED to traces in said substrate;
dispensing a first droplet of a first precursor of an encapsulating material on said top surface of said die; and
curing said first droplet to form a first dome having an outer surface over said die, said outer surface comprising a truncated sphere.

12. The method of claim 11 wherein said first droplet is allowed to cover a portion of said side surfaces prior to being cured.

13. The method of claim 11 wherein said first precursor comprises a light converting material that converts light emitted by said LED to light having a different spectrum.

14. The method of claim 11 further comprising dispensing a second droplet of a second precursor of an encapsulating material on said first droplet after said first droplet has cured to form a second dome that covers said first dome.

15. The method of claim 14 wherein said second droplet comprises an outer surface comprising a truncated sphere.

16. The method of claim 11 wherein said substrate comprises a top surface and a plurality of side surfaces, said die being attached to said top surface, and wherein said first droplet is allowed to cover a portion of said side surfaces of said substrate prior to being cured.

17 The method of claim 16 wherein said first precursor comprises a light converting material suspended in a transparent carrier and said second precursor comprises said transparent carrier without said light converting material.

18. The method of claim 17 wherein said transparent carrier comprises a transparent epoxy or silicone.

19. The method of claim 17 wherein said light converting material comprises particles of a phosphor

20. The method of claim 11 wherein said first dome comprises a diffusant.
